(19) United States
(12) Patent Application Publication
(10) Pub. No.: US 2025/0386568 A1
(43) Pub. Date: Dec. 18, 2025

(54) TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US)

(73) Assignee: Microchip Technology Incorporated, (US)

(21) Appl. No.: 18/947,478

(22) Filed: Nov. 14, 2024

Related U.S. Application Data
(60) Provisional application No. 63/661,433, filed on Jun. 18, 2024.

(51) Int. Cl. H01L 29/08; H01L 21/04; H01L 29/10; H01L 29/16; H01L 29/66; H01L 29/78

(52) U.S. Cl. CPC H10D 62/153; H01L 21/0465; H10D 12/031; H10D 30/66; H10D 62/393; H10D 62/8325

(57) ABSTRACT

A transistor that may include a silicon carbide substrate. A silicon carbide drift layer formed on the silicon carbide substrate. A well implant layer formed within the silicon carbide drift layer. A first source implant layer formed within a first portion of the well implant layer. A second source implant layer formed within a second portion of the well implant layer. An insulating layer formed over a third portion of the well implant layer and over a portion of the first source implant layer. A gate formed over the insulating layer.

### CROSS-REFERENCE TO RELATED APPLICATION

The present application claims priority to U.S. Provisional Patent Application No. 63/661,433, filed on Jun. 18, 2024, the contents of which are hereby incorporated by reference in their entirety.

### TECHNICAL FIELD

The present disclosure relates generally to transistors, and more specifically to power metal oxide semiconductor field effect transistors (MOSFETs) and methods for manufacturing same to improve short circuit withstand time of the transistor.

### SUMMARY

According to an aspect of one or more examples, there is provided a transistor that may include a silicon carbide substrate, a silicon carbide drift layer formed on the silicon carbide substrate, a well implant layer formed within the silicon carbide drift layer, a first source implant layer formed within a first portion of the well implant layer, a second source implant layer formed within a second portion of the well implant layer, an insulating layer formed over a third portion of the well implant layer and over a portion of the first source implant layer, and a gate formed over the insulating layer. The silicon carbide substrate may comprise a first concentration of a first type dopant. The silicon carbide drift layer may comprise a second concentration of the first type dopant, the first concentration may be greater than the second concentration. The well implant layer may comprise a third concentration of a second type dopant. The first source implant layer may comprise a fourth concentration of the first type dopant. The second source implant layer may comprise a fifth concentration of the first type dopant, the fifth concentration may be greater than the fourth concentration. The first type dopant may comprise an n-type dopant and the second type dopant may comprise a p-type dopant. The first type dopant may comprise a p-type dopant and the second type dopant may comprise an n-type dopant. The insulating layer may comprise polysilicon, silicon dioxide or a mixture of polysilicon and silicon dioxide.

According to an aspect of one or more examples, there is provided method of manufacturing a transistor. The method may include providing a silicon carbide substrate, forming a silicon carbide drift layer on the silicon carbide substrate, forming a well implant within the silicon carbide drift layer, forming a first source implant layer within a first portion of the well implant layer, forming a second source implant layer within a second portion of the well implant layer, forming an insulating layer over a third portion of the well implant layer and over a portion of the first source implant layer, and forming a gate over the insulating layer. The silicon carbide substrate may comprise a first concentration of a first type dopant. The silicon carbide drift layer may comprise a second concentration of the first type dopant, the first concentration may be greater than the second concentration. The well implant layer may comprise a third concentration of a second type dopant. The first source implant layer may comprise a fourth concentration of the first type dopant. The second source implant layer may comprise a fifth concentration of the first type dopant, the fifth concentration may be greater than the fourth concentration. The first type dopant may comprise an n-type dopant and the second type dopant may comprise a p-type dopant. The first type dopant may comprise a p-type dopant and the second type dopant may comprise an n-type dopant. The insulating layer may comprise polysilicon, silicon dioxide or a mixture of polysilicon and silicon dioxide.

### BRIEF DESCRIPTION OF DRAWINGS

FIG. 1 shows an illustration of a transistor according to one or more examples.

FIG. 2A is a cross sectional view of some of the steps in a method of manufacturing a transistor according to one or more examples.

FIG. 2B is a cross sectional view of some of the steps in a method of manufacturing a transistor according to one or more examples.

FIG. 2C is a cross sectional view of some of the steps in a method of manufacturing a transistor according to one or more examples.

FIG. 2D is a cross sectional view of some of the steps in a method of manufacturing a transistor according to one or more examples.

FIG. 2E is a cross sectional view of some of the steps in a method of manufacturing a transistor according to one or more examples.

FIG. 2F is a cross sectional view of some of the steps in a method of manufacturing a transistor according to one or more examples.

FIG. 2G is a cross sectional view of some of the steps in a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

Silicon carbide (SiC) is often used as a substrate to create many semiconductor devices, and may result in reduced switching losses, higher power density, improved heat dissipation, and increased bandwidth as compared with other materials. For example SiC is often used in metal-oxide-semiconductor field-effect transistors (MOSFETs), including trench MOSFETs. However, electron mobility in SiC is relatively low and results in a higher resistance than may be suitable for certain applications. Therefore, there is a need for a transistor that that may improve carrier mobility and reduce resistance.

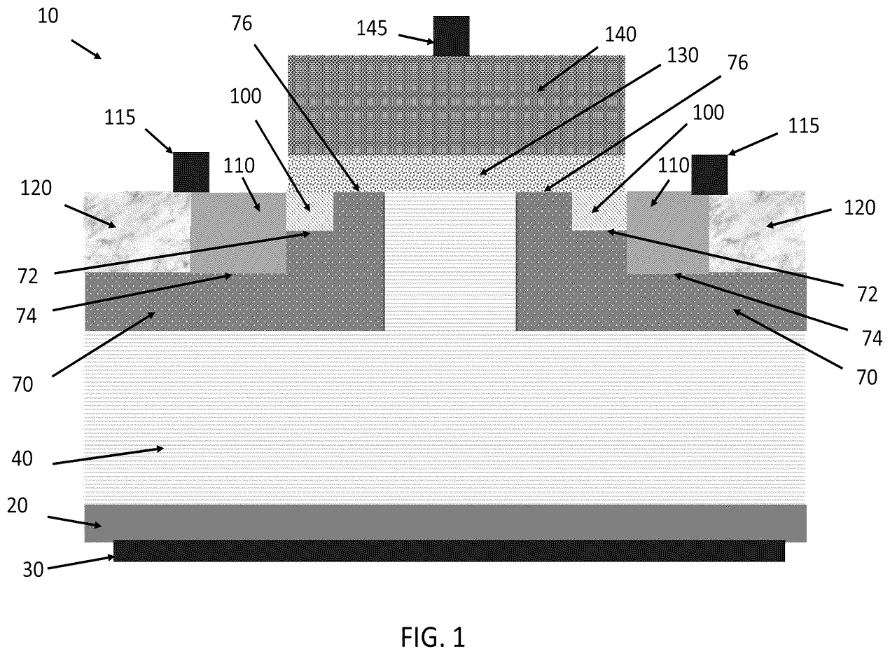

FIG. 1 shows an illustration of a transistor 10 according to one or more examples. Transistor 10 may represent, and may be called a power MOSFET, without limitation. The example transistor 10 (power MOSFET) of FIG. 1 may include a silicon carbide (SiC) substrate 20. The SiC substrate 20 shown in FIG. 1 may have a first concentration of a first type dopant, e.g., 5E18 (i.e. 5×10¹⁸). A silicon carbide drift layer 40 may be formed at one side of the SiC substrate 20 by creating a more heavily doped portion of the first type dopant (higher second concentration of first type dopant, e.g., a concentration of greater than 5E18) of the SiC substrate 20. The transistor 10 of FIG. 1 may also include a drain contact 30 formed at a first side of the SiC substrate 20, the first side of the SiC substrate 20 is opposite the second side of the SiC substrate 20 where the drift layer 40 is formed. The drain contact 30 may be made from a metal, polysilicon, or other suitable material. The example transistor 10 (power MOSFET) of FIG. 1 may include a well implant layer 70 that may be formed within the SiC drift layer 40, the well implant layer 70. The well implant layer 70 may comprise a third concentration of a second type dopant that may have a peak doping in the range 1E17 to 5E18 with a surface doping in the range 1E16 to 5E17. The source 100, 110 of the transistor 10 may be split into two parts, a first source implant layer 100 having a fourth concentration of the first type dopant (low doping) and a second source implant layer 110 having a fifth concentration of the first type dopant (high doping). The fifth concentration may be greater than the fourth concentration. The low doping second source implant layer 110 may be used to tune the resistance of the source 100, 110 of the transistor 10. The first source implant layer 100 may be formed within a first portion 72 of the well implant layer 70. The second source implant layer 110 may be formed within a second portion 74 of the well implant layer 70. Adjacent to the source 100, 110 may be the body implant layer 120 of the transistor 10. The example transistor 10 shown in FIG. 1 may include a source contact 115 operatively connected to the first source layer 100, the second source layer 110 and the body layer 120. The source contact 115 may be made from a metal, polysilicon, or other suitable material. The example transistor 10 shown in FIG. 1 may also include an insulating layer 130 formed over a third portion 76 of the well implant layer 76 and over a portion of the first source implant layer 100. The insulating layer 130 may comprise polysilicon, oxide or a mixture of polysilicon and oxide. The example transistor 10 shown in FIG. 1 may also include a poly layer 140 (gate) formed over the insulating layer 130. The poly layer 140 may comprise a metal and/or polysilicon. In FIG. 1, the example transistor 10 may include a gate electrode 145 connected to the poly layer 140. The gate electrode 145 may be made from a metal, polysilicon, or other suitable material.

In the example transistor 10 of FIG. 1, the first type dopant may be an n-type dopant with the second type dopant being a p-type dopant. Alternatively, the first type dopant may be a p-type dopant with the second type dopant being an n-type dopant.

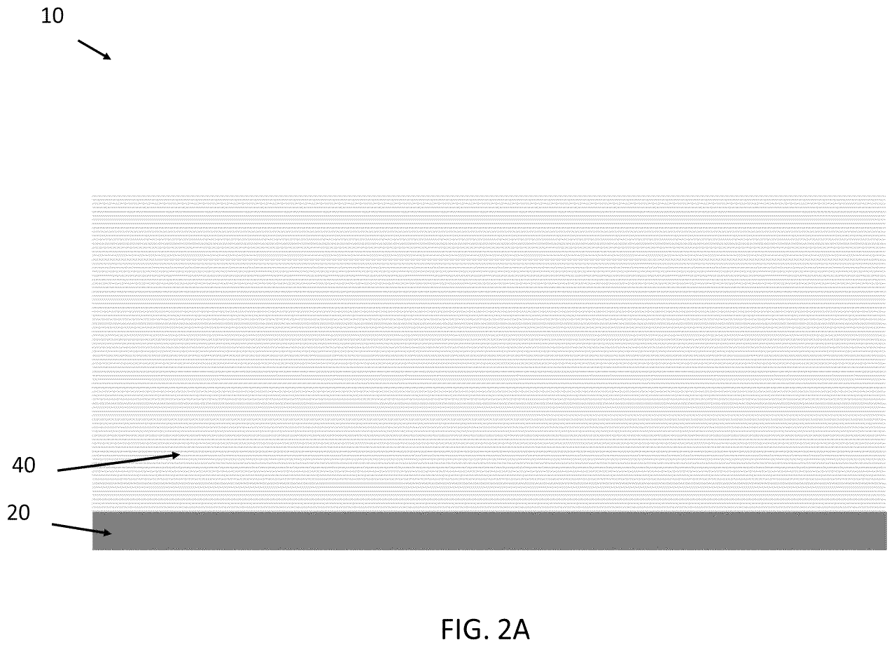

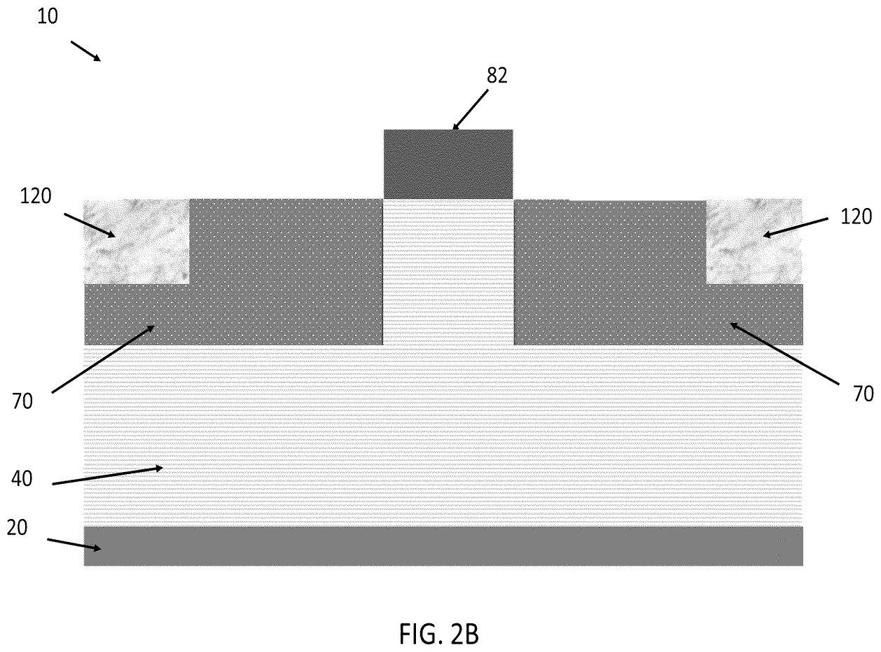

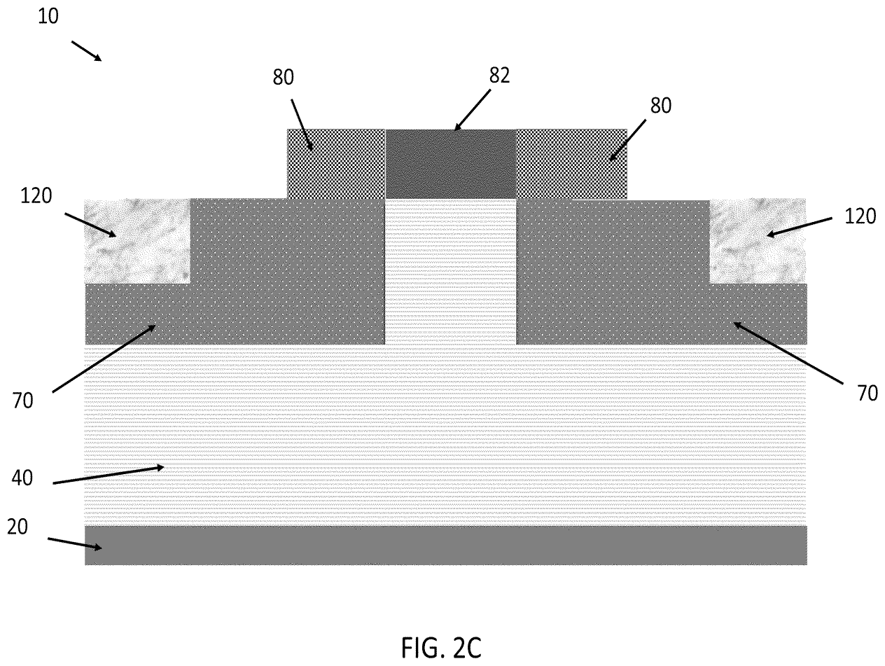

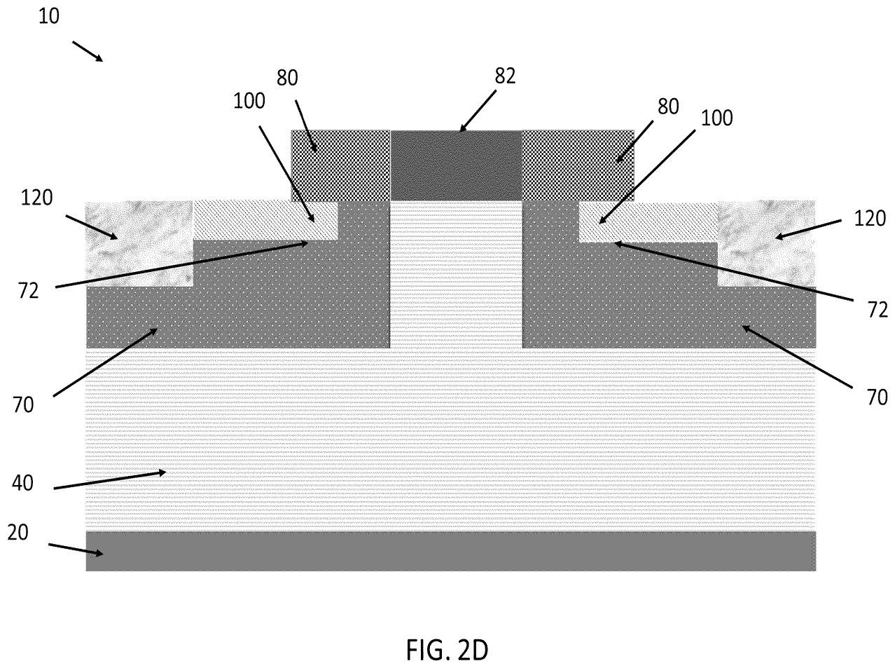

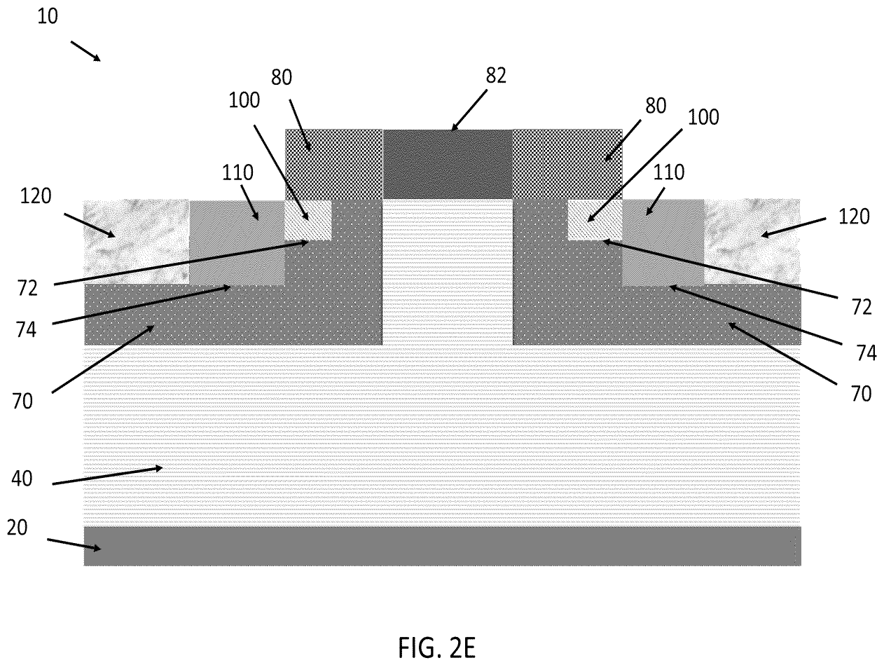

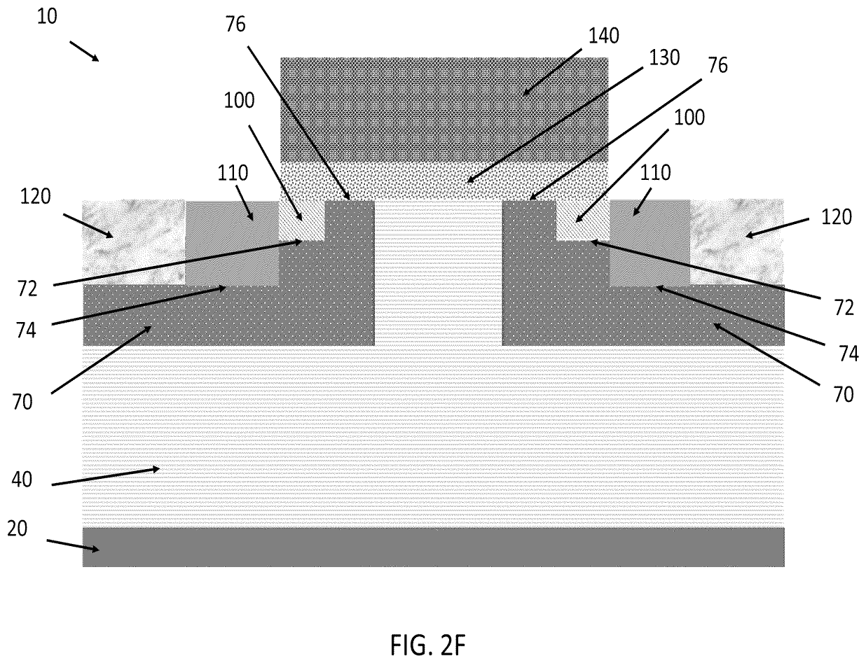

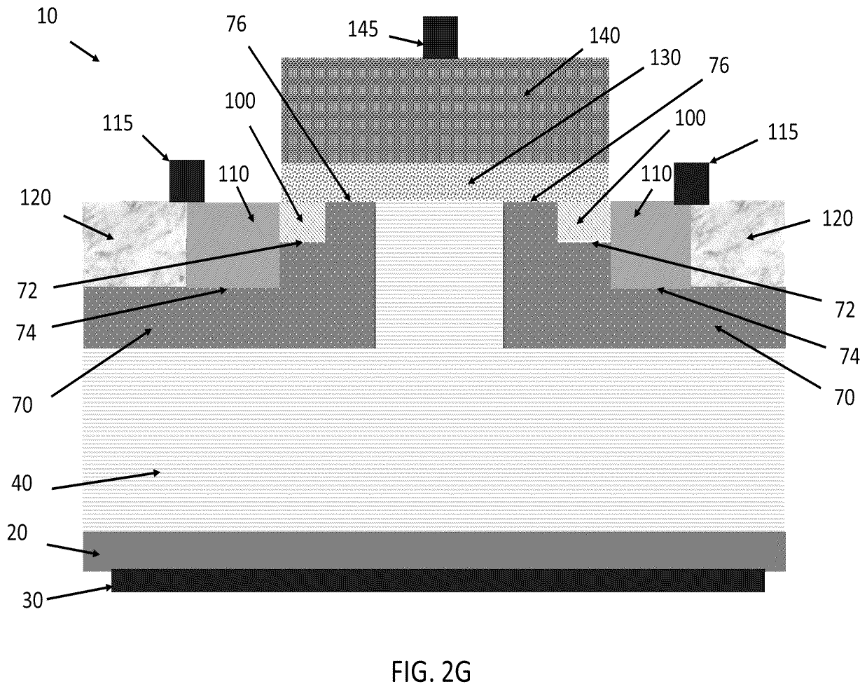

FIGS. 2A-2G show a method of manufacturing transistor 10 according to one or more examples. Although the example method shown in FIGS. 2A-2G include steps shown in a particular order, the steps may be performed in a different order, and may include additional steps that are not explicitly shown.

FIG. 2A is a cross sectional view of some of the steps in a method of manufacturing a transistor 10 according to one or more examples. In FIG. 2A, the example method may include providing a silicon carbide substrate 20 that may have a first concentration of a first type dopant, e.g., 5E18 (i.e. 5×10¹⁸). In FIG. 2A, the example method may include forming a silicon carbide drift layer 40 on the silicon carbide substrate 20. The silicon carbide drift layer 40 may have a second concentration of the first type dopant. The drift layer may be formed by a more heavily doped portion (higher second concentration of first type dopant, e.g., a concentration of greater than 5E18) of the SiC substrate.

FIG. 2B is a cross sectional view of some of the steps in a method of manufacturing a transistor 10 according to one or more examples. In FIG. 2B, the example method may include forming an implant mask 82 over a portion of the SiC drift layer 40. In FIG. 2B, the example method may include forming a well implant layer 70 within the SiC drift layer 40. In FIG. 2B, the example method may include forming a body implant layer 120 within the well implant layer 70. The well implant layer 70 may comprise a third concentration of a second type dopant. The well implant layer 70 may have a peak doping in the range 1E17 to 5E18 with a surface doping in the range 1E16 to 5E17.

FIG. 2C is a cross sectional view of some of the steps in a method of manufacturing a transistor 10 according to one or more examples. In FIG. 2C, the example method may include forming a spacer 80 on both sides of the implant mask 82. The spacer 80 may at least partially overlap the well implant layer 70.

FIG. 2D is a cross sectional view of some of the steps in a method of manufacturing a transistor 10 according to one or more examples. In FIG. 2D, after the spacer 80 was formed in FIG. 2C, the example method may include implanting a first source implant layer 100 within a first portion 72 of the well implant layer 70. The first source implant layer 100 may comprise a fourth concentration of the first type dopant (low doping) and may have a concentration in the range of 1E18-1E20.

FIG. 2E is a cross sectional view of some of the steps in a method of manufacturing a transistor 10 according to one or more examples. In FIG. 2E, the example method may include enlarging the spacer 80 to at least partially overlap the first source implant layer 100. In FIG. 2E, the example method may include implanting a second source implant layer 110 within a second portion 74 of the well implant layer 70. The second source implant layer 110 may comprise a fifth concentration of the first type dopant (high doping). The fifth concentration may be greater than the fourth concentration. The low doping of the first source implant layer 100 may be used to tune the resistance of the source 100, 110 of the transistor 10.

FIG. 2F is a cross sectional view of some of the steps in a method of manufacturing a transistor 10 according to one or more examples. In FIG. 2F, the implant mask 82 of FIGS. 2B-2E and spacers of FIGS. 2C-2E may be removed. In FIG. 2F, the example method may include forming an insulating layer 130 over a third portion 76 of the well implant layer 70 and over a portion of the first source implant layer 100. The insulating layer 130 may comprise polysilicon, oxide or a mixture of polysilicon and oxide. In FIG. 2F, the example method may include forming a poly layer 140 (gate) over the insulating layer 130. The poly layer 140 may comprise a metal and/or polysilicon.

FIG. 2G is a cross sectional view of some of the steps in a method of manufacturing a transistor 10 according to one or more examples. In FIG. 2G, the example method may include forming a source contact 115 operatively connected to the first source layer 100, the second source layer 110 and the body layer 120. The source contact 115 may be made from a metal, polysilicon, or other suitable material. In FIG. 2G, the example method may include forming a gate electrode 145 operatively connected to the poly layer 140. The gate electrode 145 may be made from a metal, polysilicon, or other suitable material. In FIG. 2G, the example method may include forming a drain contact 30 at a first side of the SiC substrate 20, the first side of the SiC substrate 20 is opposite the second side of the SiC substrate 20 where the drift layer 40 is formed. The drain contact 30 may be made from a metal, polysilicon, or other suitable material.

The example method of manufacturing transistor 10 of FIGS. 2A-2G may have the first type dopant be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a silicon carbide substrate;
a silicon carbide drift layer formed on the silicon carbide substrate;
a well implant layer formed within the silicon carbide drift layer;
a first source implant layer formed within a first portion of the well implant layer;
a second source implant layer formed within a second portion of the well implant layer;
an insulating layer formed over a third portion of the well implant layer and over a portion of the first source implant layer; and
a gate formed over the insulating layer.

2. The transistor of claim 1, wherein the silicon carbide substrate comprises a first concentration of a first type dopant.

3. The transistor of claim 2, wherein the silicon carbide drift layer comprises a second concentration of the first type dopant, the first concentration is greater than the second concentration.

4. The transistor of claim 3, wherein the well implant layer comprises a third concentration of a second type dopant.

5. The transistor of claim 4, wherein the first source implant layer comprises a fourth concentration of the first type dopant.

6. The transistor of claim 5, wherein the second source implant layer comprises a fifth concentration of the first type dopant, the fifth concentration is greater than the fourth concentration.

7. The transistor of claim 6, wherein the first type dopant comprises an n-type dopant and the second type dopant comprises a p-type dopant.

8. The transistor of claim 6, wherein the first type dopant comprises a p-type dopant and the second type dopant comprises an n-type dopant.

9. The transistor of claim 1, wherein the insulating layer comprises polysilicon, silicon dioxide, or a mixture of polysilicon and silicon dioxide.

10. A method of manufacturing a transistor, the method comprising:
providing a silicon carbide substrate;
forming a silicon carbide drift layer on the silicon carbide substrate;
forming a well implant within the silicon carbide drift layer;
forming a first source implant layer within a first portion of the well implant layer;
forming a second source implant layer within a second portion of the well implant layer;
forming an insulating layer over a third portion of the well implant layer and over a portion of the first source implant layer; and
forming a gate over the insulating layer.

11. The method of claim 10, wherein the silicon carbide substrate comprises a first concentration of a first type dopant.

12. The method of claim 11, wherein them silicon carbide drift layer comprises a second concentration of the first type dopant, the first concentration is greater than the second concentration.

13. The method of claim 12, wherein well implant layer comprises a third concentration of a second type dopant.

14. The method of claim 13, wherein the first source implant layer comprises a fourth concentration of the first type dopant.

15. The method of claim 14, wherein the second source implant layer comprises a fifth concentration of the first type dopant, the fifth concentration is greater than the fourth concentration.

16. The method of claim 15, wherein the first type dopant comprises an n-type dopant and the second type dopant comprises a p-type dopant.

17. The method of claim 15, wherein the first type dopant comprises a p-type dopant and the second type dopant comprises an n-type dopant.

18. The method of claim 10, wherein the insulating layer comprises polysilicon, silicon dioxide, or a mixture of polysilicon and silicon dioxide.
